(19) United States
(12) Patent Application Publication
(10) Pub. No.: US 2005/0196973 A1
(43) Pub. Date: Sep. 8, 2005

(54) Plasma nitriding method

(75) Inventors: Nobumasa Suzuki, Moriya-shi (JP); Hideo Kitagawa, Moriya-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/071,246

(22) Filed: Mar. 4, 2005

(30) Foreign Application Priority Data
Mar. 4, 2004 (JP) 061204/2004(PAT.)

(51) Int. Cl. H01L 21/4763

(52) U.S. Cl. 438/778

(57) ABSTRACT

Disclosed is a plasma nitriding method by which an ultra-thin oxide-nitride film having a half-value depth of not greater than 0.8 nm can be produced, overcoming various inconveniences involved in conventional plasma nitriding methods. In one preferred form of the present invention, the plasma nitriding method includes the steps of introducing a substrate to be processed, into a reaction chamber, evacuating the reaction chamber, supplying a gas containing nitrogen atoms, into the reaction chamber at a predetermined flow rate, adjusting an exhaust conductance to maintain a predetermined pressure inside the reaction chamber, and applying an electric voltage into the reaction chamber to produce plasma to thereby cause nitriding of the surface of the substrate, wherein the gas further contains hydrogen atoms, wherein the predetermined pressure is not less than 2 Torr, and wherein a spacing between the substrate and a densest portion of the plasma is not less than 75 nm.

### FIELD OF THE INVENTION AND RELATED ART

This invention relates to a method of nitriding the surface of a substrate. More particularly, the invention concerns a plasma nitriding method for nitriding the surface (sub-surface or ultra-shallow surface) of a substrate in a shallow depth and at high concentration.

With recent advancements of microprocessing technology, production of ULSI devices having MOS-FET of a gate length of tens nanometers is now enabled. With such reduction of gate length, on the other hand, it is now required to make the gate insulating film thickness 1.5 nm or less, in accordance with what is called the scaling (proportional reduction) law. However, if a silicon oxide film is made thin, there arises a problem that, due to the tunnel effect, the gate leak current flowing through the insulative film increases.

In consideration of this, attempts have been made to use what is called “High-k film” (high dielectric film) having high dielectric constant such as Ta₂O₅, AlSiO or HfSiO (Thin Film Hafnium Silicate), in place of silicon oxide film, However, for practical use, there still remain many problems to be solved such as compatibility with other materials and processes, for example.

Hence, investigations have been made to use silicon nitride film or oxide-nitride film which has been showed good results in respect to material and process although the dielectric constant is lower than the High-k film, and yet which film has good barrier function to diffusion of impurities such as B (boron) from a gate electrode into the substrate. Generally, such films are produced on the basis of CVD method such as LP-CVD or PE-CVD. However, because of too much leak current or interfacial level, use of such method is impractical.

Hence, investigations have been made to use a method in which a gas containing nitrogen is excited by plasma to cause nitrization of the surface of a silicon substrate or silicon oxide film. Since the silicon nitride film or oxide-nitride film produced in this manner is small in interfacial level or leak current, they are regarded as successful next generation gate insulation film.

In order to accomplish shallow nitrization with various densities including a high density, use of high density and low electron-temperature plasma such as surface wave plasma would be effective. Such surface wave plasma nitriding may be carried out as follows. That is, a processing gas is introduced into a processing chamber of a surface wave plasma nitriding apparatus, and microwave energies are supplied into the processing chamber from a microwave supplying apparatus, provided outside the processing chamber, through a microwave transmitting window to produce plasma. This causes excitation of gas, dissociation and reaction, and the surface of a substrate placed within the processing chamber is processed thereby.

Since in the surface wave plasma processing, microwaves are used as an excitation source for the gas, electrons can be accelerated at high-frequency and up to required energies through the electron plasma wave electric-field having high frequency. Therefore, gas molecules can be dissociated and excited efficiently. Thus, where a surface wave plasma processing apparatus is used, there are advantages that the electrolytic dissociation efficiency of the gas as well as excitation efficiency and decomposition efficiency are high, and thus a plasma of high density and low electron temperature can be produced relatively easily, and that high-speed and high-quality processing can be done at a low temperature. Furthermore, since the microwaves have a property that it can pass through a dielectric material, the plasma processing apparatus can be constructed as an electrode-less discharge type. This provides an advantage that the plasma processing can be done very cleanly.

The inventor of the subject application has proposed in U.S. Pat. No. 5,487,875, U.S. Pat. No. 5,538,699, and U.S. Pat. No. 6,497,783 examples of such surface plasma processing apparatus having an endless circular waveguide with plural slots formed in an H-shaped surface, as an efficient and uniform microwave introducing device. FIG. 3 of the drawings shows this type of microwave plasma processing apparatus. In FIG. 3, denoted at 501 is a plasma processing chamber, and denoted at 502 is a substrate to be processed. Denoted at 503 is a support for the substrate 502, and denoted at 504 is a substrate temperature adjusting means. Denoted at 505 is a plasma processing gas introducing means provided around the plasma processing chamber. Denoted at 506 is an exhaust, and denoted at 507 is a dielectric material window for separating the plasma processing chamber 501 from the atmosphere side. Denoted at 508 is an electric voltage introducing means, and it comprises a slotted endless circular waveguide for introducing microwaves into the plasma processing chamber 501 through the dielectric material window 507.

The plasma nitriding is carried out as follows. First, the plasma processing chamber 501 is vacuum evacuated through an exhaust system (not shown). Subsequently, a gas containing nitrogen atoms is introduced into the plasma processing chamber 501 through the gas introducing means 505, provided around the plasma processing chamber 501, at a predetermined flow rate. Thereafter, a conductance valve (not shown) provided in the exhaust system (not shown) is adjusted to create and hold a predetermined pressure inside the plasma processing chamber 501. Then, a desired electric voltage is supplied from a microwave voltage source (not shown) into the plasma processing chamber 501 through the endless circular waveguide 506 Here, the microwaves introduced into the endless circular waveguide 508 pass through the dielectric window 507 and enter the plasma processing chamber 501, thereby to produce high-density plasma there. The processing gas is excited by the thus produced plasma, and the surface of the substrate 502 placed on the supporting table 503 is nitrided thereby.

By use of such surface wave plasma processing apparatus, high-density and low-electron-temperature plasma having an electron density not less than 10¹² cm⁻³, and electron temperature not greater than 2 eV and a sheath potential not greater than 10V can be produced inside a large diameter space having a diameter of about 300 mm, uniformly with a uniformness not greater than ±3%. Thus, high density and shallow nitriding can be done in a short time.

However, where it is desired to produce an ultra-thin oxide-nitride film by the surface nitriding using a surface wave plasma processing apparatus such as described above, since the main component that determines the nitrogen profile is ions being accelerated by the sheath field and driven into the substrate surface, even with a plasma of sufficiently low electron temperature it is very difficult to obtain an ultra-thin oxide-nitride film having a half-value depth of not greater than 0.8 nm.

Although it may be asserted that high pressure processing causes radical dominance as like “radical mode”, even in such case what determines the profile is ions having relatively high energy and, thus, it is unable to reduce the half-value depth significantly. Furthermore, because the ion flux decreases, performing high-density nitriding in a short period becomes difficult to attain.

### SUMMARY OF THE INVENTION

It is accordingly an object of the present invention to provide a plasma nitriding method for a substrate surface, by which at least one of the inconveniences involved in conventional plasma nitriding methods described above can be solved and by which an ultra-thin oxide-nitride film having a half-value depth of not greater than, 0.8 nm can be produced.

In accordance with an aspect of the present invention, there is provided a plasma nitriding method, comprising the steps of: introducing a substrate to be processed, into a reaction chamber; evacuating the reaction chamber; supplying a gas containing nitrogen atoms, into the reaction chamber at a predetermined flow rate; adjusting an exhaust conductance to maintain a predetermined pressure inside the reaction chamber; and applying an electric voltage into the reaction chamber to produce plasma to thereby cause nitriding of the surface of the substrate; wherein the gas further contains hydrogen atoms, wherein the predetermined pressure is not less than 2 Torr, and wherein a spacing between the substrate and a densest portion of the plasma is not less than 75 mm.

It has been confirmed that, with this arrangement of the present invention, an ultra-thin oxide-nitride film having a half-value depth not greater than 0.8 nm can be produced.

In accordance with the plasma nitriding method of the present invention, a gas or mixed gas containing nitrogen atoms as well as hydrogen atoms may be used The spacing between the substrate and the densest portion of the plasma may be kept at 75 mm or more, and the pressure may be set at 2 Torr or higher. By carrying out the plasma nitriding process under these conditions, NH₄⁺ ion dominant nitriding can be accomplished. Therefore, the electron temperature and, in turn, the injected ion energy can be reduced remarkably. Thus, a plasma nitriding method by which an ultra-thin oxide-nitride film or a nitride film having a half-value depth of 8 nm or less can be provided.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic and sectional view of a plasma processing apparatus, for explaining a plasma processing method according to the present invention.

FIG. 2A is a graph for explaining the dependence of NH₄/N₂ ion density ratio upon the pressure, for supplementary explanation of a plasma processing method according to the present invention.

FIG. 2B is a graph for explaining the dependence of NH₄/N₂ ion density ratio upon the window and the substrate spacing, for supplementary explanation of a plasma processing method according to the present invention.

FIG. 3 is a schematic and sectional view of a conventional plasma processing apparatus.

### DESCRIPTION OF THE PREFERRED EMBODIMENTS

Preferred embodiments of the present invention will now be described with reference to the attached drawings.

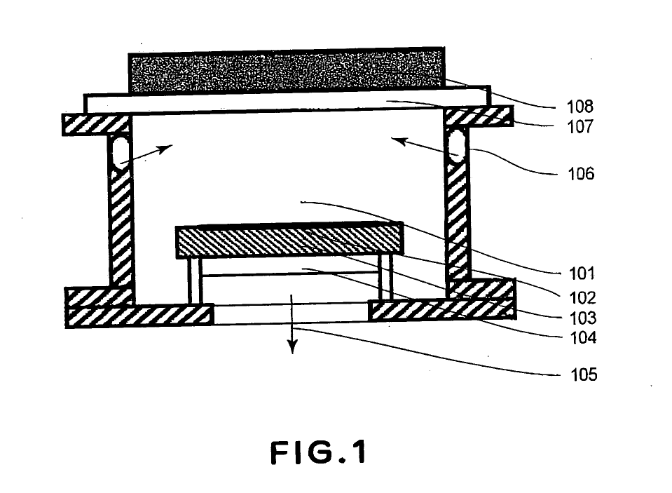

Referring first to FIG. 1, a plasma nitriding processing method according to an embodiment of the present invention will be explained.

Denoted in FIG. 1 at 100 is denoted is a plasma processing chamber, and denoted at 102 is a substrate to be processed, which is disposed with a distance of 50 mm or more from a highest intensity portion of plasma, adjacent a window. Denoted at 103 is a support table for the substrate 102, and denoted at 104 is a substrate temperature adjusting means. Denoted at 105 is a plasma processing gas introducing means provided around the plasma processing chamber 101, for introducing plasma processing gas that contains nitrogen atoms and hydrogen atoms. Denoted at 106 is an exhaust, and denoted at 108 is an electric voltage introducing means for applying an electric voltage into the plasma processing chamber 101.

The plasma nitriding process is carried out as follows. First, the plasma processing chamber 101 is vacuum evacuated through an exhaust system (not shown). Subsequently, a gas that contains nitrogen atoms and hydrogen atoms is introduced into the plasma processing chamber 101 through the gas introducing means 105, provided around the plasma processing chamber 101, at a predetermined flow rate. Thereafter, a conductance valve (not shown) provided in the exhaust system (not shown) is adjusted to create and hold a predetermined pressure of not lower than 1 Torr inside the plasma processing chamber 101. Then, a desired electric voltage is applied into the plasma processing chamber 101 from the voltage applying means 108, thereby to produce plasma therein. By means of the thus produced plasma, the processing gas being introduced from the periphery is exited, ionized and reacted and, hence, it is activated to thereby nitride the surface of the substrate 102 placed on the supporting table 103.

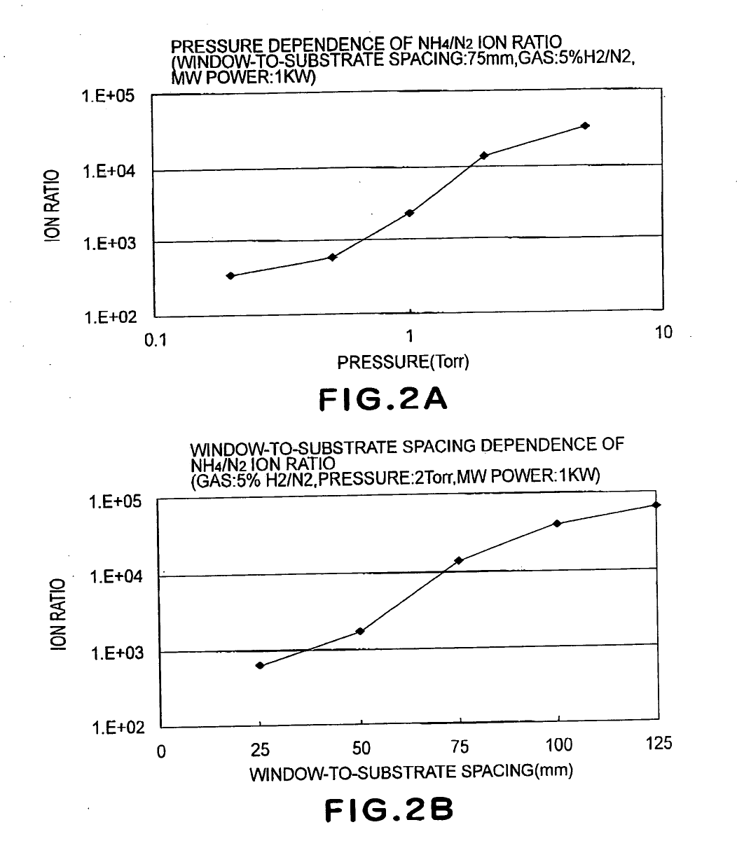

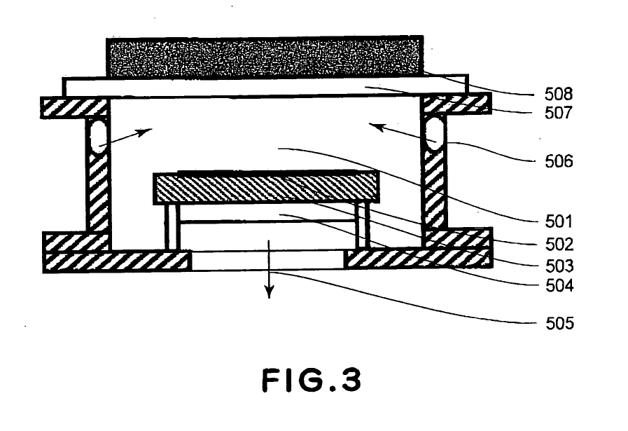

FIG. 2A shows the dependence of NH₄/N₂ ion density ratio upon the pressure, and FIG. 2B shows the dependence of NH₄/N₂ ion density ratio upon the window and the substrate spacing, both in a case where 5% H2/N₂ gas is used as the nitriding processing gas. It is seen from FIG. 2A that, where the window to substrate distance is 75 mm, the ion density ratio increases at a pressure of 2 to 3 Torr, and the nitriding reaction changes to NH₄⁺ dominance. Further, it is seen from FIG. 2B that, where the pressure is 2 Torr, the ion density ratio increases at a window to substrate distance of 75 to 100 mm, and the nitriding reaction changes to NH₄ dominance.

In that occasion, the main component that determines the nitriding profile is NH₄⁺ ions which can be accelerated by a sufficiently low sheath electric field. Thus, a very shallow nitriding profile is obtainable thereby.

As regards the gas usable in the plasma nitriding processing method of the present invention, it may be any gas that can produce NH₄ within plasma such as, for example, (a) a single gas that contains NH bond such as NH₃ (ammonia) or N₂H₄ (hydrazine), for example, or alternatively a mixture of such gas as diluted by noble gas or N₂ (nitrogen), and (b) a mixed gas of a gas that contains nitrogen atoms such as N₂ and a gas that contains hydrogen atoms such as H₂, CH₄, SiH₄, Si₂H₆, for example, or alternatively a mixture of such gas as diluted by noble gas.

As regards the pressure to be used in the plasma nitriding processing method of the present invention, a pressure not lower than 2 Torr (more preferably, not lower than 3 Torr) with which the ion density ratio increases and NH₄⁺ dominance is accomplished is appropriate.

As regards the spacing between the substrate and the plasma densest portion (adjacent the window in the case of surface wave plasma), a distance not less than 75 mm (more preferably, not less than 100 mm) with which the ion density ratio increases and the NH₄⁺ dominance is accomplished is appropriate.

In the plasma nitriding processing method of the present invention, for increased ion density ratio, a conductance control plate may be disposed between the plasma producing portion and the substrate supporting means. Such conductance control plate may comprise, as an example, a flat plate-like member having a plurality of holes formed therein. As regards the material of the conductance control plate, it may be Si series insulative material such as quartz or silicon nitride, for example.

As regards the voltage supplying means usable in the plasma nitriding processing method of the present invention, use of one that can provide microwaves in a sheet-like form such as a slotted endless circular waveguide or a coaxial introduction plane multislot antenna, for example, will be most appropriate. However, any other device can be uses as long as it produces plasma.

In accordance with the plasma nitriding processing method of the present invention, the gas to be used can be chosen appropriately, while Si, Al, Ti, Zn, Ta, etc. may be used as the substrate or the surface layer to be processed, and the substrate or the surface layer can be nitrided thereby.

Specific example of the microwave plasma nitriding processing method of the present invention will be described below. However, it should be noted that the present invention is not limited to those examples.

### EXAMPLE 1

The microwave plasma processing apparatus as shown in FIG. 1 was used, and surface nitriding processing for an ultra-thin gate oxide film of a semiconductor logic device was carried out.

As regards the substrate 102, a P-type monocrystal silicon substrate (with surface azimuth <100> and electrical resistivity 10 Ωcm) of 8-inch diameter having an oxide film 1.2 nm, was used. First, the silicon substrate 102 was placed on the substrate supporting table 103, and the plasma processing chamber 101 was vacuum evacuated by use of an exhaust system (not shown). The silicon substrate 102 was heated and kept at 300° C. Then, a mixed gas of N₂ having H₂ added by 5% was introduced into the processing chamber 101 through the plasma processing gas introducing port 105 at a flow rate 3 slm. Subsequently, a conductance valve (not shown) provided in the exhaust system (not shown) was adjusted, to create and keep a pressure 3 Torr within the processing chamber 101. Thereafter, from a microwave voltage source of 2.45 GHz (not shown), an electric power of 1.0 kW was supplied through the slotted endless. circular waveguide 108. Thus, plasma was produced inside the processing chamber 101, and the processing was carried out for 15 seconds.

In this procedure, the mixed gas introduced through the plasma processing gags introducing inlet 105 is excited inside the plasma processing chamber and, through mutual reaction, it produces NH₄⁺ which reaches the substrate 102 surface by much more amount than ion species, whereby only the surface (sub-surface or ultra-shallow surface) is nitrided.

After the nitriding processing, evaluations were carried out with respect to depth profile, equivalent oxide thickness (EOT), interfacial level density (C-V characteristic in the case of 1 MHz RF application obtainable through a capacity measuring device), and so on. The results showed that: the nitrogen peak density was 12%, the half-value depth was very shallow as of 0.5 nm, and the EOT was very thin as of 1.0 nm, the interfacial (surface) level was sufficiently low and satisfactory C-V characteristic was obtained.

### EXAMPLE 2

The microwave plasma processing apparatus as shown in FIG. 1 was used, and surface nitriding processing for a gate oxide film of a semiconductor memory device was carried out.

As regards the substrate 102, a P-type monocrystal silicon substrate (with surface azimuth <100> and electrical resistivity 10 Ωcm) of 8-inch diameter having an oxide film 3.0 nm, was used. First, the silicon substrate 102 was placed on the substrate supporting table 103, and the plasma processing chamber 101 was vacuum evacuated by use of an exhaust system (not shown). The silicon substrate 102 was heated and kept at 300° C. Then, a mixed gas of N₂ having NH₃ added by 5% was introduced into the processing chamber 101 through the plasma processing gas introducing port 105 at a flow rate 3 slm. Subsequently, a conductance valve (not shown) provided in the exhaust system (not shown) was adjusted, to create land keep a pressure 3 Torr within the processing chamber 101. Thereafter, from a microwave voltage source of 2.45 GHz (not shown), an electric power of 1.0 kW was supplied through the slotted endless circular waveguide 108. Thus, plasma was produced inside the processing chamber 101, and the processing was carried out for 40 seconds.

In this procedure, the mixed gas introduced through the plasma processing gas introducing inlet 105 is excited and reacted inside the plasma processing chamber, and it produces NH₄⁺ which reaches the substrate 102 surface by much more amount than ion species, whereby the surface (sub-surface or ultra-shallow surface) is nitrided.

After the nitriding processing, like the first example, evaluations were carried out with respect to depth profile, EOT, C-V characteristic and so on. The results showed that: the nitrogen peak density was 30%, the half-value depth was very shallow as of 0.8 nm, and the EOT was very thin as of 2.1 nm, the interfacial level was sufficiently low and satisfactory C-V characteristic was obtained.

### EXAMPLE 3

The microwave plasma processing apparatus as shown in FIG. 1 was used, and direct nitriding processing for a silicon substrate of a semiconductor logic device was carried out.

As regards the substrate 102, a P-type monocrystal silicon substrate (with surface azimuth <100> and electrical resistivity 10 Ωcm) of 8-inch diameter, with its natural oxide film removed by washing, was used. First, the silicon substrate 102 was placed on the substrate supporting table 103, and the plasma processing chamber 101 was vacuum evacuated by use of an exhaust system (not shown) The silicon substrate 102 was heated and kept at 300° C. Then, a mixed gas of Ar having N₂H₄ added by 5% was introduced into the processing chamber 101 through the plasma processing gas introducing port 105 at a flow rate 2 slm. Subsequently, a conductance valve (not shown) provided in the exhaust system (not shown) was adjusted, to create and keep a pressure 2 Torr within the processing chamber 101. Thereafter, from a microwave voltage source of 2.45 GHz (not shown), an electric power of 1.0 kW was supplied through the slotted endless circular waveguide 108. Thus, plasma was produced inside the processing chamber 101, and the processing was carried out for 240 seconds.

In this procedure, the mixed gas introduced through the plasma processing gas introducing inlet 105 is excited and reacted inside the plasma processing chamber, and it produces NH₄⁺ which reaches the substrate 102 surface by much more amount than ion species, whereby the surface (sub-surface or ultra-shallow surface) is nitrided.

After the nitriding processing, like the first example, evaluations were carried out with respect to depth profile, EOT, C-V characteristic and so on. The results showed that: the half-value depth was very shallow as of 0.6 nm, and the EOT was very thin as of 0.9 nm, the interfacial level was sufficiently low and satisfactory C-V characteristic was obtained.

### EXAMPLE 4

The microwave plasma processing apparatus as shown in FIG. 1 was used, and pre-film-formation grounding nitriding processing for a high dielectric-constant (permittivity) gate oxide film of a semiconductor logic device was carried out.

As regards the substrate 102, a P-type monocrystal silicon substrate (with surface azimuth <100> and electrical resistivity 10 Ωcm) of 8-inch diameter, with its natural oxide film removed by washing, was used. First, the silicon substrate 102 was placed on the substrate supporting table 103, and the plasma processing chamber 101 was vacuum evacuated by use of an exhaust system (not shown) The silicon substrate 102 was heated and kept at 300° C. Then, a mixed gas of Ar having NH₃ added by 5% was introduced into the processing chamber 101 through the plasma processing gas introducing port 105 at a flow rate 3 slm Subsequently, a conductance valve (not shown) provided in the exhaust system (not shown) was adjusted, to create and keep a pressure 3 Torr within the processing chamber 101. Thereafter, from a microwave voltage source of 2.45 GHz (not shown), an electric power of 1.0 kw was supplied through the slotted endless circular waveguide 108. Thus, plasma was produced inside the processing chamber 101, and the processing was carried out for 180 seconds.

In this procedure, the mixed gas introduced through the plasma processing gas introducing inlet 105 is excited and reacted inside the plasma processing chamber, and it produces NH₄⁺ which reaches the substrate 102 surface by much more amount than ion species, whereby the surface (sub-surface or ultra-shallow surface) is nitrided.

After the nitriding processing, HfSiO film of 4 nm thickness was formed as a high permittivity insulative film in accordance with a CVD method. Subsequently, like the first example, evaluations were carried out with respect to depth profile, EOT, C-V characteristic and so on. The results showed that: the half-value depth was very shallow as of 0.6 nm, and the EOT was very thin as of 0.8 nm, the interfacial level was sufficiently low and satisfactory C-V characteristic was obtained.

### EXAMPLE 5

The microwave plasma processing apparatus as shown in FIG. 1 was used, and surface nitriding processing for a control gate oxide film of a flash memory was carried out.

As regards the substrate 102, a P-type monocrystal silicon substrate (with surface azimuth <100> and electrical resistivity 10 Ωcm) of 8-inch diameter, having 6 nm oxide film adhered on a floating gate electrode, was used. First, the silicon substrate 102 was placed on the substrate supporting table 103, and the plasma processing chamber 101 was vacuum evacuated by use of an exhaust system (not shown). The silicon substrate 102 was heated and kept at 300° C. Then, a mixed gas of N₂ having H₂ added by 5% was introduced into the processing chamber 101 through the plasma processing gas introducing port 105 at a flow rate 3 slm. Subsequently, a conductance valve (not shown) provided in the exhaust system (not shown) was adjusted, to create and keep a pressure 2 Torr within the processing chamber 101. Thereafter, from a microwave voltage source of 2.45 GHz (not shown), an electric power of 1.0 kW was supplied through the slotted endless circular waveguide 108. Thus, plasma was produced inside the processing chamber 101, and the processing was carried out for 180 seconds.

In this procedure, the mixed gas introduced through the plasma processing gas introducing inlet 105 is excited and reacted inside the plasma processing chamber, and it produces NH₄ which reaches the substrate 102 surface by much more amount than ion species, whereby the surface (sub-surface or ultra-shallow surface) is nitrided.

After the nitriding processing, like the first example, evaluations were carried out with respect to depth profile, C-V characteristic and so on. The results showed that: the half-value depth was very shallow as of 0.7 nm, and satisfactory C-V characteristic was obtained.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2004-061204 filed Mar. 4, 2004, for which is hereby incorporated by reference.

1. A plasma nitriding method, comprising the steps of:
introducing a substrate to be processed, into a reaction chamber;
evacuating the reaction chamber;
supplying a gas containing nitrogen atoms, into the reaction chamber at a predetermined flow rate;
adjusting an exhaust conductance to maintain a predetermined pressure inside the reaction chamber; and
applying an electric voltage into the reaction chamber to produce plasma to thereby cause nitriding of the surface of the substrate;
wherein the gas further contains hydrogen atoms, wherein the predetermined pressure is not less than 2 Torr, and wherein a spacing between the substrate and a densest portion of the plasma is not less than 75 mm.

2. A method according to claim 1, wherein the gas consists of NH bond containing gas having noble gas or N₂ mixed therein.

3. A method according to claim 2, wherein the NH bond containing gas is NH₃ or N₂H₄.

4. A method according to claim 1, wherein the gas consists of mixed gas of nitrogen atom containing gas and hydrogen atom containing gas, or a mixture of those further having noble gas mixed therein.

5. A method according to claim 5, wherein the nitrogen atom containing gas is N₂, and the hydrogen atom containing gas is H₂.

6. A method according to claim 1, wherein the predetermined pressure is not less than 3 Torr.

7. A method according to claim 1, wherein the spacing between the substrate and the densest portion of the plasma is not less than 100 mm.

8. A method according to claim 1, wherein an electric field effective to reflect positive ions from the plasma is produced between the substrate and a plasma producing region.

9. A method according to claim 1, wherein a magnetic field effective to trap ions from the plasma is produced between the substrate and a plasma producing region.

10. A method according to claim 1, wherein the electric voltage is supplied by use of a microwave voltage supplying multislot antenna.

11. A method according to claim 1, wherein the electric voltage is supplied by use of a slotted endless circular waveguide.
